(19) United States
(12) Patent Application Publication
(10) Pub. No.: US 2022/0379250 A1
(43) Pub. Date: Dec. 1, 2022

(54) TRAP FOR VACUUM LINE, INSTALLATION AND USE

(71) Applicant: PFEIFFER VACUUM, Annecy (FR)

(72) Inventors: Pascal MOINE, Annecy (FR); Thierry NEEL, Annecy (FR)

(73) Assignee: PFEIFFER VACUUM, Annecy (FR)

(21) Appl. No.: 17/773,779

(22) PCT Filed: Oct. 28, 2020
(86) PCT No.: PCT/EP2020/080283

§ 371 Date: May 2, 2022

(30) Foreign Application Priority Data
Nov. 6, 2019 (FR) FR1912458

(51) Int. Cl. B01D 45/08; C23C 16/44; H01L 21/67

(52) U.S. Cl. CPC B01D 45/08; C23C 16/4412; H01L 21/67017

(57) ABSTRACT

A trap is provided for a vacuum line to be mounted on a pipe connected to a reactor, the trap including: a chamber including an inlet and a bottom wall; an outlet tube in communication with the chamber and including another inlet, the inlet and the outlet tube are configured to be connected to the pipe and to permit passage of a flow of gas to be pumped coming from the reactor; and a deflector between the inlet and the another inlet, the bottom wall being below the another inlet and being an annular cup or an adjustable height cup, and conformed so as to cooperate with the deflector to permit an accumulation of solid elements in the bottom wall when the flow of gas is reduced and to expel the solid elements from the chamber by aerodynamic entrainment when the flow of gas is increased.

The present invention relates to a trap for a vacuum line, in particular intended to be mounted at the outlet of a reactor used in methods for the fabrication of semiconductors. The invention also relates to an installation equipped with said trap and to a use of said trap.

Some pumping devices are employed in so-called “powder” processes because they employ gases generating large quantities of solid byproducts able to remain for long periods in the vacuum pump. This is the case for example of some methods for fabricating semiconductors, in particular HARP (High Aspect Ratio Process) methods for depositing thin layers in a vacuum, in particular of type CVD, PECVD, SACVD, ALD.

These vacuum deposition methods generally alternate deposition steps in which process gases are introduced into the reactor to deposit thin layers on silicon wafers with cleaning steps in which active gases are introduced into the reactor after the wafers are removed to clean the walls of the reactor.

However, in vacuum lines situated downstream of the reactor these reactions are not controlled. The active gases used in the cleaning steps, such as acid gases like HF, H+ protons or fluorine radicals F, form catalysts for the reactions of polymerization of the deposition byproducts, generally of an organic or organometallic nature. These encounters between chemical species can cause the formation of polymerized agglomerated byproducts that are difficult to evacuate because they are particularly viscous and adherent.

To prevent polymerized byproducts polluting the pumping devices it is known to use traps in the vacuum lines. Those traps separate the solid byproducts from the gases, for example by gravity or centrifugal force or again by condensation or thermolysis, and retain the solid byproducts by accumulation.

A problem is that the accumulation of powders in the trap increases the probability of encounters between species of different chemical nature. A result of this is that unwanted chemical reactions, such as the polymerization reactions previously mentioned, can appear and be favoured. Also, the high temperatures of these traps, generally between 140° C. and 170° C. inclusive, furnish the activation energy encouraging the appearance of these chemical reactions.

These traps must therefore be cleaned very regularly. Maintenance must be frequent to prevent the polymerized byproducts having time to harden. As well as being laborious and frequent, these maintenance operations are costly because they necessitate shutting down the pumping device and consequently shutting down the equipment for fabricating wafers.

An object of the present invention is to propose an improved device at least partly solving one of the disadvantages of the prior art.

To this end, the invention has for object a trap for a vacuum line intended to be mounted on a pipe connected to a reactor, the trap including a chamber and an outlet tube communicating with the chamber, the inlet of the chamber and the outlet tube being intended to be connected respectively to the pipe of the vacuum line upon the passage of a flow of gas to be pumped coming from the reactor, the trap including a deflector disposed between the inlet of the chamber and the inlet of the outlet tube, the chamber including a bottom wall situated below the inlet of the outlet tube, characterized in that the bottom wall is produced in the form of an annular cup or in the form of a cup adjustable in height, conformed to cooperate with the deflector to enable an accumulation of the solid elements in the bottom wall when the flow of gas to be pumped is moderate or weak and to expel the solid elements from the chamber by aerodynamic entrainment through the effect of a strong flow of gas to be pumped.

A moderate or weak flow of gas to be pumped is for example less than 150 slm (253.5 Pa·m³/s).

A strong flow of gas to be pumped, such as a flow greater than 200 slm (338 Pa·m³/s), is a flow of gas greater than the moderate or weak flow of gas. This is for example the flow of gas that is evacuated from the reactor of the installation during a step of establishing a vacuum in a method of depositing thin layers for the fabrication of semiconductors, known as the HARP method, also known as the “Pump down” method.

The outlet tube, the chamber and the deflector therefore enable at least partial separation, in particular by gravity, of the gases to be pumped from the solid elements entering the chamber, in particular the solid byproducts.

When the flow of gas is weak or moderate the byproducts remain at least partly trapped in the bottom wall whereas the lighter gases are entrained toward the pumping device.

The outlet tube, the chamber, in particular the bottom wall of the chamber, and the deflector are also conformed to evacuate the solid elements by aerodynamic entrainment toward the outlet tube because of the effect of a strong flow of gas to be pumped, which enables self-cleaning of the trap.

The trap may further have one or more of the features that are described hereinafter, taken separately or in combination.

In accordance with a first embodiment, the outlet tube penetrates into the chamber. The bottom wall surrounds the outlet tube and is produced in the form of an annular cup.

The side walls of the chamber and of the outlet tube may be cylindrical and coaxial.

The deflector may include a concave screen facing the inlet of the chamber, the edges of the concave screen being extended by a skirt surrounding the outlet tube. The curved shape of the concave screen enables collection of the agglomerated solid elements, for example in the form of flakes, coming from the flow of gas or torn from the vacuum line by the flow of gas. Moreover, the concave screen enables guiding of the rising flow of gas along the edges of the concave screen, the flow of gas being afterwards deflected toward the bottom by the chamber. Moreover, the internal walls of the skirt and of the concave screen enable deflection of the flow of gas rising along the outlet tube toward the inlet of the latter.

The cooperation of the deflector and the walls of chamber therefore guides the trajectory of the gases in the trap, either to deposit the solid elements in the curved surfaces in laminar flow or to evacuate them out of the trap in turbulent flow.

In accordance with a variant embodiment, the deflector is fastened to a tubular base of the outlet tube, the tubular base being removable.

Moreover, the outlet tube may include at least one tubular raiser spacer configured to raise the deflector. The tubular raiser spacers enable action on the compromise between the efficacy of the sweeping out effect linked to the level of turbulence and the efficacy of the pumping reflecting the level of conductance.

In accordance with a variant embodiment, the deflector includes a helix arranged coaxially with the axis of the cylindrical chamber. The helix is of the “cyclone uniflow” type, that is to say generating a gas vortex favouring the separation of the solid elements from the gases in limited spaces. This embodiment of the deflector enables the overall size of the trap to be reduced.

In accordance with a second embodiment, the outlet tube is connected to a side wall of the chamber, the bottom wall being produced in the form of a cup adjustable in height.

The trap may further include an actuating means configured to cause the bottom wall to slide in the chamber in the direction of the axis of the cylindrical chamber. Adjusting the position in height of the cup enables optimization of the operation of the trap in terms of accumulating or sweeping out solid elements.

The deflector has for example a frustoconical duct general shape forming an inlet guide. The funnel formed in this way orients the gases and the dust toward the bottom wall produced for example in the form of a cup adjustable in height.

The frustoconical duct has for example an axis coaxial with the axis of the chamber of cylindrical general shape. Alternatively, the frustoconical duct is off-centred. Either of these geometries can influence the gas-solid separation rate differently.

In accordance with another example, the deflector has a bevelled cylindrical duct general shape forming an inlet guide, the bevel being open at a lower end of the deflector.

Moreover, according to one embodiment, the trap includes a cooling device configured to cool the bottom wall of the chamber.

The cooling device may be a double-bottom enclosure closed by the bottom wall of the chamber. The double-bottom enclosure has a liquid inlet and a liquid outlet for the circulation of a cooling liquid. The bottom wall of the chamber can therefore be maintained at ambient temperature instead of being heated, in particular by conduction by the pumping device. Reducing the temperature of the bottom of the chamber reduces the chemical kinetic, which renders the medium less favourable to chemical reactions. Moreover, the cooled solid elements remain in powder form. They are therefore less sticky or pasty and therefore easier to entrain by a flow of gas.

The internal walls of the trap intended to be placed in communication with the flow of gas to be pumped may be coated with a chemically inert coating, such as dense Al₂O₃, Y₂O₃ or Y₂F₃. The coating may also have non-stick and/or hydrophobic properties, such as an NiP-PTFE coating or such as fluorinated or non-fluorinated polymer coatings, or any other similar hydrophobic coating. These surface coatings favour the evacuation of the solid elements by limiting their adhesion to the walls.

The trap may include at least one injection nozzle configured to inject a purge gas into the chamber in the direction of the bottom wall. Injecting a purge gas can enable replacement or assistance of the flow of gas to be pumped to evacuate the solid elements out of the chamber by aerodynamic entrainment. The injection nozzle is for example configured to inject a strong flow of gas, for example greater than 200 slm (338 Pa·m³/s).

The injection nozzle may be configured to inject purge gas peaks in an intermittent manner, that is to say to inject the purge gas in a pulsed manner to alternate repetitively a phase of injection with a phase with no injection of purge gas.

Intermittent injection enables detachment of the solid elements from the curved surfaces of the deflector and/or from the bottom wall of the chamber to be encouraged.

The chamber may include a removable cover. A removable cover enables access to the bottom of the chamber to clean it without needing to remove the trap from the pipe, in particular in the event of reception of debris that cannot be evacuated by a gas flow.

The trap may further include at least one porthole formed in the removable cover and/or in the side wall of the chamber.

The at least one porthole in particular enables visual confirmation whether deposits, debris or other solid elements have accumulated in the chamber.

It also enables the installation of optical surveillance devices to assist diagnosing clogging.

For example, the trap includes first and second portholes formed in the side wall of the chamber and an optical surveillance device configured to send light through the first porthole and to measure the light crossing the chamber through the second porthole.

Moreover, according to one embodiment, the at least one porthole includes an annular curtain device configured to form a purge gas screen in front of a window of the porthole.

The invention also consists in an installation including:
a vacuum line including a pumping device, and
a reactor an outlet of which is connected to a pipe of the vacuum line, characterized in that it further includes a trap as described above mounted on the pipe upstream of the pumping device in the direction of circulation of the gases to be pumped.

The reactor is a reactor used in methods for the fabrication of semiconductors, such as a reactor used in methods of depositing thin layers alternating with steps of deposition followed by steps of establishing a vacuum, with cleaning steps.

The vacuum line may be configured to be heated only over a first pipe portion situated between the reactor and the trap, for example to a temperature greater than 100° C., such as 170° C.

The vacuum line may include a regulator valve on this first pipe portion, arranged at the outlet of the reactor, to control the pressure of the gases in the reactor.

The vacuum line may also include a heated powder trap on this first pipe portion, downstream of the regulator valve in the direction of the pumped gases.

Heating this first pipe portion favours the physical aspect of the states of the material by enabling conservation of the pumped elements in gas form, preventing their condensation or solidification, in particular when they are cooled by adiabatic expansion caused by the effect of rapid pressure variations generated by the regulator valve.

The second portion of the vacuum line, including the pumping device, possibly a valve for isolating the pumping device and a trap as described above, is not heated. This second pipe portion may even be cooled to favour conjointly the physical aspect of the states of the material and the chemical aspect of the reactions. The solid elements cooled or not heated remain in the form of non-cohesive powders. They are easier to evacuate by pumping and the lowered temperature enables restriction of the appearance of unwanted chemical reactions upstream of the pumping device.

The invention also consists in a use of a trap as described above, connected to a reactor used in methods of depositing thin films for the fabrication of semiconductors, alternating deposition steps followed by steps to establish a vacuum with cleaning steps, characterized in that:
during the deposition step a weak or moderate flow of gas crosses the trap and enables solid elements to accumulate by sedimentation in the bottom wall, and
during the step of establishing a vacuum, a strong flow of gas crosses the trap and at least partly entrains the solid elements out of the chamber toward a pumping device.

The cyclic occurrence of a strong flow of gas in the reactor, after each deposition step and before each cleaning step, is exploited here to sweep out the solid elements previously accumulated in the curved surfaces of the trap.

The trap can therefore be cleansed of most of the solid elements before the arrival of the active cleaning gases. When the cleaning step begins and the active cleaning gases are sent into the reactor, the solid elements resulting from the deposition step have been swept out. The probability is minimized of encounters between the organic (or metallo organic) species of the deposition steps and the acid/active/radical species of the cleaning steps, which limits polymerization reactions.

Maintenance of the trap can therefore be reduced, or even entirely eliminated.

The invention also consists in a use of a trap as described above, connected to any type of reactor, characterized in that a strong purge gas is injected into the trap, for example via an injection nozzle of the trap, in pulsed or non-pulsed manner, for a predefined time, to facilitate at least partial driving of the solid elements out of the chamber.

The invention also consists in an installation including:
a vacuum line including a pumping device, and
a reactor an outlet of which is connected to a pipe of the vacuum line, characterized in that the vacuum line is configured to be heated, for example to a temperature greater than 100° C., such as 170° C., only over a first pipe portion terminating at least one metre from the pumping device.

The reactor is for example a reactor used in methods for the fabrication of semiconductors.

The vacuum line may include a regulator valve on this first pipe portion, arranged at the outlet of the reactor, to control the pressure of the gases in the reactor.

The vacuum line may also include a heated powder trap on this first pipe portion, downstream of the regulator valve in the direction of the pumped gases.

Heating this first pipe portion favours the physical aspect of the states of the material by enabling conservation of the pumped elements in gas form, preventing their condensation or solidification, in particular when they are cooled by adiabatic expansion because of the effect of rapid variations of pressure generated by the regulator valve.

The second portion of the vacuum line, including the pumping device, possibly a valve for isolating the pumping device, is not heated. This second pipe portion may even be cooled to favour conjointly the physical aspect of the states of the material and the chemical aspect of the reactions. The cooled or non-heated solid elements remain in the form of non-cohesive powders. They are easier to evacuate by pumping and the lower temperature enables restriction of the appearance of unwanted chemical reactions upstream of the pumping device.

Other features and advantages of the invention will emerge from the following description given by way of non-limiting example with reference to the appended drawings, in which:

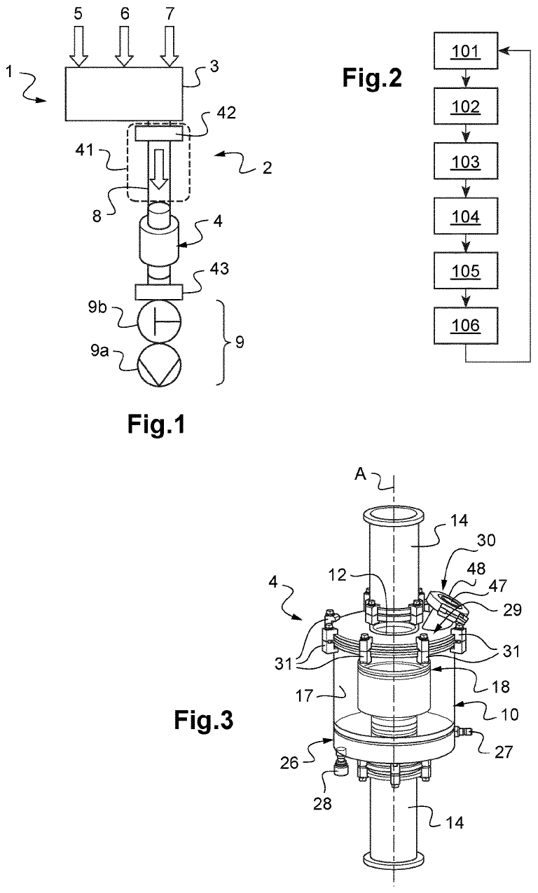

FIG. 1 represents a schematic view of an installation in which only the elements necessary to understand the invention are represented.

FIG. 2 is a flowchart of one example of a cycle of a method carried out in a reactor of the installation.

FIG. 3 shows a perspective view of a first embodiment of a trap of the installation, the side wall of the chamber of the trap being represented as if transparent.

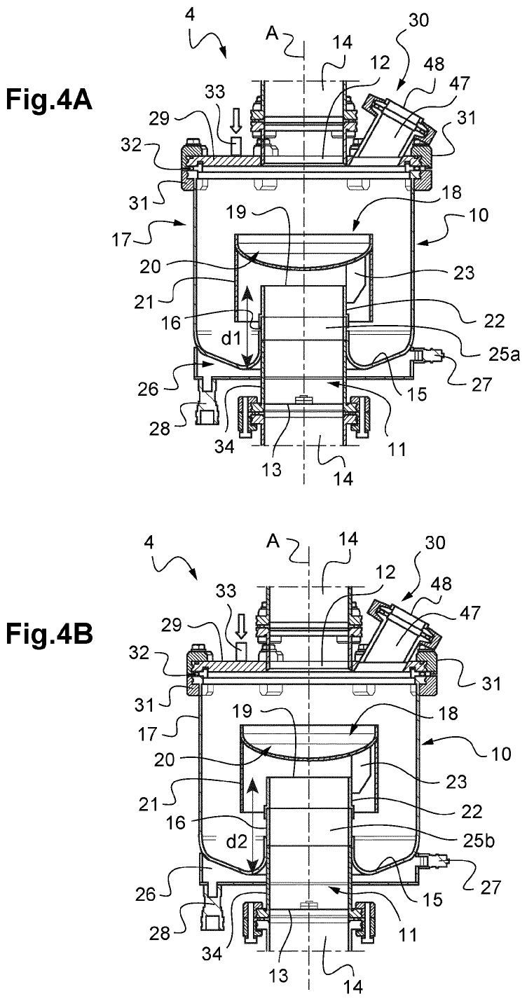

FIG. 4A shows a partial view in section of the trap from FIG. 3 with a first example of a tubular raiser spacer.

FIG. 4B shows a view similar to FIG. 4A for a second example of a tubular raiser spacer.

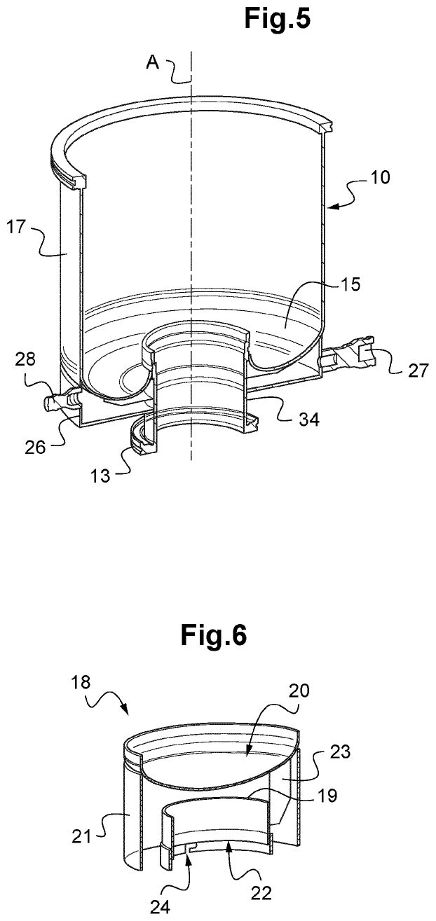

FIG. 5 shows a view in section of a cooling device and of a chamber with no cover of the trap from FIG. 3.

FIG. 6 shows a view in section of a deflector and of a tubular base of the trap from FIG. 3.

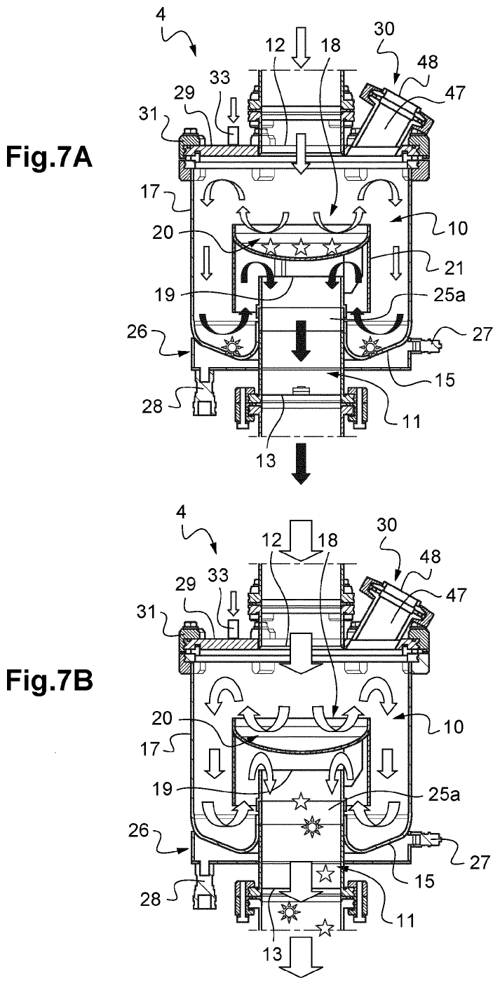

FIG. 7A shows the trap from FIG. 4A on which are schematically represented the trajectory of the pumped gases and the solid elements accumulated during a deposition step taking place in the reactor.

FIG. 7B is a view similar to FIG. 7A during a later step of establishing a vacuum in the reactor.

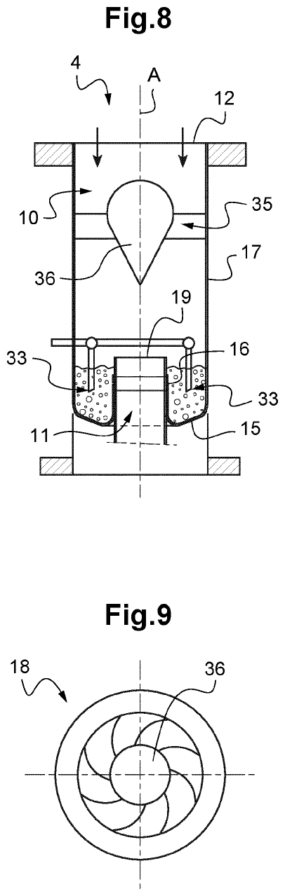

FIG. 8 is a schematic view in section of a trap according to a second embodiment.

FIG. 9 is a view from above of a helix of the trap from FIG. 8.

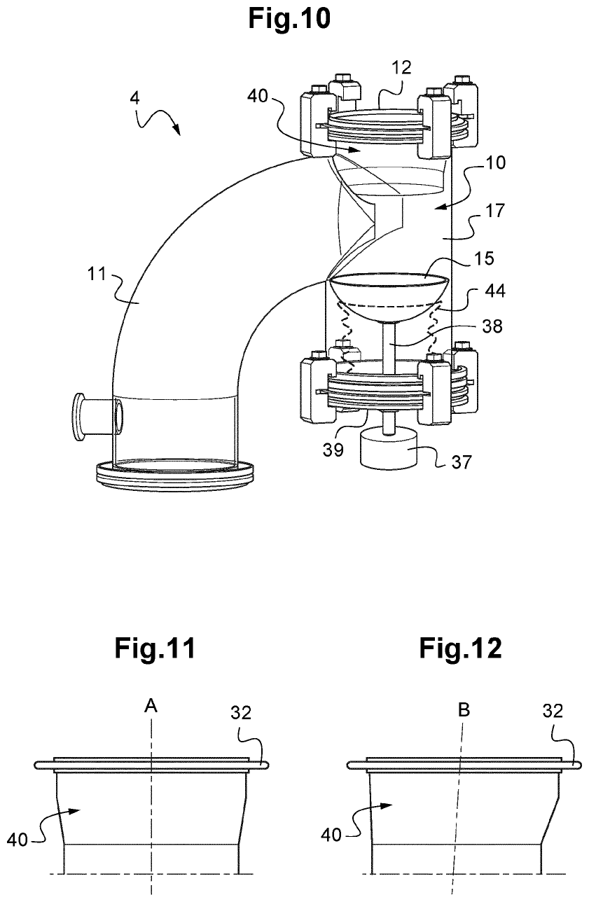

FIG. 10 shows a perspective view of a third embodiment of a trap of the installation, the side walls of the chamber and of the outlet tube being represented as if transparent.

FIG. 11 shows a perspective view of the deflector from FIG. 10.

FIG. 12 shows a variant embodiment of the deflector from FIG. 11.

FIG. 13 shows a view similar to FIG. 10 for another variant embodiment of the deflector.

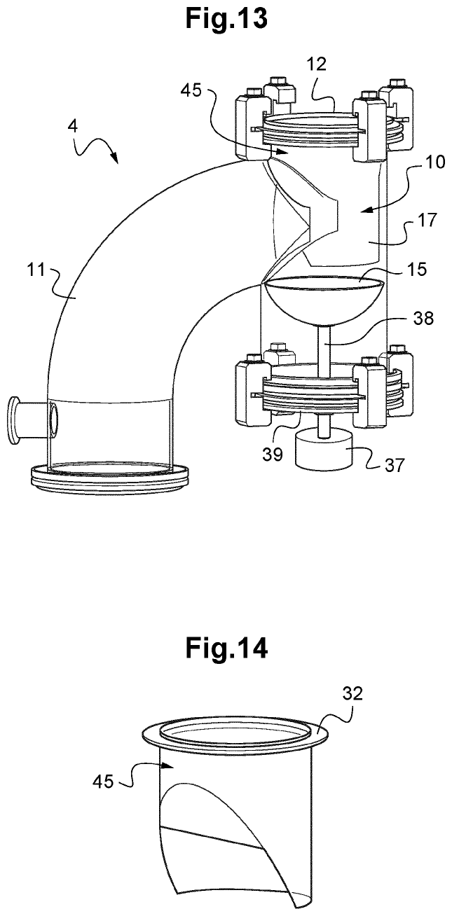

FIG. 14 shows a perspective view of the deflector from FIG. 13.

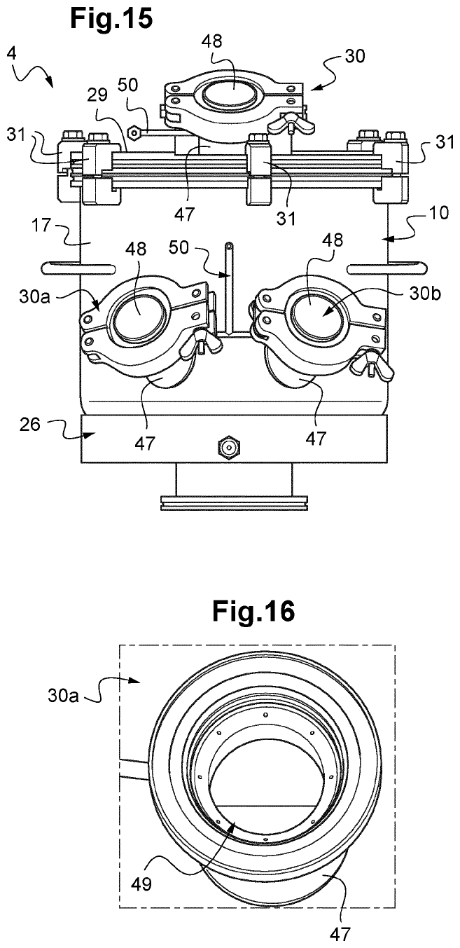

FIG. 15 shows a view in perspective of a fourth embodiment of a trap.

FIG. 16 shows a view to a larger scale of a detail of the trap from FIG. 15.

In these figures identical elements bear the same reference numbers.

The following embodiments are examples. Although the invention refers to one or more embodiments, this does not necessarily mean that each reference concerns the same embodiment or that the features apply only to only one embodiment. Single features of different embodiments may also be combined or interchanged to furnish other embodiments.

There is meant by “upstream” an element that is placed before another relative to the direction of circulation of the gas. In contrast, by “downstream” is meant an element that is placed after another relative to the direction of circulation of the gases to be pumped.

The terms “top”, “bottom”, “upper part” and “lower part” are defined with reference to the disposition of the elements of a trap disposed with the bottom down.

FIG. 1 shows an example of an installation 1. The installation 1 includes a vacuum line 2, a reactor 3 and a trap 4.

The reactor 3 is for example a reactor used in methods for the fabrication of semiconductors, that is to say processes used in the fabrication of microelectronic devices on substrates, such as silicon wafers, such as a method of disposing alternating thin layers of the deposit steps 102 followed by the vacuum establishing steps 103, with cleaning steps 105.

The method is for example a high aspect ratio process (HARP) deposition process such as of SACVD (Sub Atmospheric Chemical Vapour Deposition) type, alternating steps of deposition at a subatmospheric pressure followed by steps of establishing a vacuum, with cleaning steps. In this method, the subatmospheric pressure is below atmospheric pressure but greater than 400 Torr, such as between 500 and 600 Torr inclusive.

An example of a cycle of a method is shown in FIG. 2, such as an example of an HARP type deposition method.

One or more substrates, for example two substrates in a reactor 3 of two or three litres, for example, are first introduced into the reactor 3 at low pressure (loading step 101).

Then, during a deposition step 102, lasting for example between 10 and 15 minutes, process gases 5, generally of organic or metallo organic nature, are introduced into the reactor 3 to deposit thin layers onto the substrates at a subatmospheric pressure, generally greater than 500 Torr, such as 600 Torr. The flow of process gas 5 is generally between 10 slm (16.9 Pa·m³/s) and 100 slm (169 Pa·m³/s), or less than 150 slm (253.5 Pa·m³/s), which is considered weak or moderate.

At the end of the deposition step 102 the process gases 5 are evacuated from the reactor 3 in a very short vacuum establishing phase (also known as “pump down”) 103, lasting less than 5 seconds and during which the pressure in the reactor 3 is lowered to a pressure of 1 Torr. The flow of pumped gas is generally between 300 slm (507 Pa·m³/s) and 400 slm (676 Pa·m³/s) inclusive, i.e. greater than 200 slm (338 Pa·m³/s), which is considered strong.

There follows a step 104 of offloading substrates at low pressure.

Once the substrates are offloaded, active cleaning gases 7 such as NF₃ are introduced into the reactor 3 and a plasma is generated in the reactor 3 to clean the walls (cleaning step 105). The cleaning step 105 may last a few minutes. Throughout the duration of the cleaning step 105 the active cleaning gases 7 are evacuated from the reactor 3.

A purge step 106 may follow, for example with injection of a neutral gas 6, such as nitrogen, into the reactor 3.

The cycle can thereafter be reiterated with a new insertion of substrates (loading step 101).

Returning to FIG. 1, it is seen that the vacuum line 2 includes a pipe 8 and a pumping channel 9.

The suction inlet of the pumping device 9 is connected to the outlet of the reactor 3 by the pipe 8.

The pumping device 9 is for example a pumping unit including a primary vacuum pump 9a and a Roots type vacuum pump 9b mounted in series and upstream of the primary vacuum pump 9a in the direction of circulation of the gases to be pumped (represented by an arrow in FIG. 1).

The trap 4 is for example mounted on the pipe 8, upstream of the pumping device 9.

FIGS. 3 to 7B show a first embodiment.

As can be seen better in FIGS. 4A and 4B, the trap 4 includes a chamber 10 and an outlet tube 11 communicating with the chamber 10. The inlet 12 of the chamber 10 and the outlet tube 11 are respectively intended to be connected to the pipe 8 of the vacuum line 2 on the passage of a flow of gas to be pumped coming from the reactor 3.

In the first example the inlet 12 of the chamber 10 and the outlet tube 11 are situated on opposite sides of the chamber 12. For example, the inlet 12 of the chamber 10 is situated in the upper part of the chamber 10 and the outlet tube 11 is situated in the lower part.

The inlet 12 is connected to the pipe 8 either directly or for example via connectors 14, in particular straight connectors, such as pipe portions. The connectors 14 may be mounted elements assembled to the trap 4 and to the pipe 8 or integrated into the trap 4, such as into the walls of the chamber 10 and of the outlet tube 11.

The side walls 17, 16 of the chamber 10 and of the outlet tube 11 are for example cylindrical and coaxial with the longitudinal axis A (FIGS. 4A and 4B). The cylindrical side walls 17, 16 may be coaxial with the pipe 8, for example cylindrical. Thus the chamber 10 and the outlet tube 11 include neither bends nor returns liable to create dead zones or losses of conductance.

As can be seen in FIGS. 4A, 4B and 5, the chamber 10 includes a bottom wall 15 situated below the inlet 19 of the outlet tube 11.

In the first embodiment the outlet tube 11 penetrates into the chamber 10. The bottom wall 15 surrounds the outlet tube 11 and is produced in the form of an annular cup. To be more precise the bottom wall 15 of the chamber 10 surrounding the outlet tube 11 is for example inclined downwardly and curved upwardly to join the side wall 16 of the outlet tube 11, forming a curved annular surface around the outlet tube 11.

The trap 4 further includes a deflector 18 disposed between the inlet 12 of the chamber 10 and the inlet 19 of the outlet tube 11.

In the first embodiment the deflector 18 faces the inlet 12 of the chamber 10 and shelters the inlet 19 of the outlet tube 11. An interstice is moreover formed between the deflector 18 and the outlet tube 11 to enable the circulation of the gases to be pumped.

The annular cup of the bottom wall 15 is conformed to cooperate with the deflector 18 to enable accumulation of the solid elements in the annular cup when the flow of gas to be pumped is moderate or weak and to expel the solid elements from the chamber 10 by aerodynamic entrainment due to the effect of a strong flow of gas to be pumped.

A moderate or weak flow of gas to be pumped is for example less than 150 slm (253.5 Pa·m³/s). This is in particular the case of the flows of gas injected into the reactor 3 during the deposition step 103.

A strong flow of gas to be pumped, such as greater than 200 slm (338 Pa·m³/s), is a flow of gas greater than the moderate or weak flow of gas. This is in particular the flow of gas that is evacuated from the reactor 3 of the installation 1 during the step 103 of establishing a vacuum.

The outlet tube 11 penetrating into the chamber 10 and the deflector 18 therefore enable at least partial separation, in particular by gravity, of the gases to be pumped from the solid elements entering into the chamber 10, in particular the solid byproducts. The latter remain trapped in the annular cup around the outlet tube 11 whereas the lighter gases are entrained toward the pumping device 9. The shape of the annular cup of the bottom wall 15 of the chamber 10, inclined downwardly and curved upwardly, is also conformed to evacuate the solid elements from the chamber 10, which are entrained by aerodynamic entrainment toward the outlet tube 11 due to the effect of a strong flow of gas to be pumped, which enables self-cleaning of the trap 4.

In accordance with an embodiment seen better in FIGS. 4A, 4B and 6, the deflector 18 includes a concave screen 20 facing the inlet 12 of the chamber 10. The edges of the concave screen 20 are extended by a skirt 21 surrounding the outlet tube 11. The skirt 21 is for example cylindrical and coaxial with the longitudinal axis A.

The deflector 18 has a multiple role.

In addition to protecting the inlet 19 of the outlet tube 11, its shape enables guiding of the flow of gas into the trap 4.

The particular curved shape of the concave screen 20 of the deflector 18 enables collection of the heaviest or the most dense solid elements coming from the flow of gas.

Furthermore, the concave screen 20 enables guiding of the upward flow of gas along the edges of the concave screen 20, the flow of gas thereafter being deflected toward the bottom of the chamber 10 by the internal walls of the chamber 10. Moreover, the internal walls of the skirt 21 and of the concave screen 20 of the deflector 18 enable deflection of the rising flow of gas along the outlet tube 11 towards the inlet 19 of the latter. The cooperation of the deflector 18 and of the walls of the chamber 10 thus guides the trajectory of the gases into the trap 4, either to deposit the solid elements in the curved surfaces or to evacuate them from the trap 4.

In accordance with one example the deflector 18 is fastened to a tubular base 22 removable from the outlet tube 11.

The tubular base 22 includes for example a cylinder having the same diameter as a downstream portion 34 of the outlet tube 11. The downstream portion 34 is for example formed in one piece with the side wall 17 and the bottom wall 15 of the chamber 10 (FIG. 5).

The concave screen 20 of the deflector 18 is for example retained on the tubular base 22 by a sector 23 (FIG. 6).

The tubular base 22 may include a fixing means 24 configured to cooperate removably with the downstream portion 34 of the outlet tube 11. The fixing means 24 includes for example at least one bayonet fixing, the L-shaped openings of the bayonet fixing being for example carried by the tubular base 22 and the complementary pins carried by the downstream portion 34.

In accordance with one embodiment the outlet tube 11 includes at least one tubular raiser spacer 25a, 25b configured to raise the deflector 18.

The tubular raiser spacer 25a, 25b is for example disposed between the downstream portion 34 and the tubular base 22. The tubular raiser spacer 25a, 25b has for example the same inside diameter as the downstream portion 34 of the outlet tube 11 and of the tubular base 22. It can for example be inserted in the downstream portion 34 of the outlet tube 11 and into the tubular base 22.

Two examples of tubular raiser spacers 25a, 25b are shown in FIGS. 4A and 4B, the spacer 25b in FIG. 4B being higher than the spacer 25a in FIG. 4A, to extend the height of the outlet tube 11 and thus to move the inlet 19 of the outlet tube 11 farther away from the bottom wall 15.

When the deflector 18 is in a low position, with no tubular raiser spacer or with a small tubular raiser spacer 25a, the sweeping out effect of the gas is accentuated in the bottom of the chamber 10 because of the high speed of the gases.

Using tubular raiser spacers 25a, 25b enables the deflector 18 to be raised to reduce the head loss generated by the trap 4.

The choice of the height of the deflector 18 is therefore a compromise between the efficacy of the sweeping out effect and the pumping efficacy.

The trap 4 may further include a cooling device 26 configured to cool the bottom wall 15 of the chamber 10 (seen better in FIG. 5).

The cooling device 26 is for example a double-bottom enclosure closed by the bottom wall 15 of the chamber 10, the double-bottom enclosure including a liquid inlet 27 and a liquid outlet 28 for the circulation of a cooling liquid in the enclosure. The cooling liquid is for example water, for example at 20° C., that is to say water at ambient temperature.

The bottom wall 15 of the chamber 10 can therefore be maintained at ambient temperature instead of being heated, in particular by conduction by the pumping device 9.

Reducing the temperature of the bottom of the chamber 10 reduces the chemical kinetic, which renders the medium less favourable to chemical reactions. Moreover, the less cohesive cooled solid elements remain in powder form. They are therefore less sticky or pasty and therefore easier to entrain by a flow of gas.

The cover 29 of the chamber 10 is for example a flat disk in which the inlet orifice 12 of the chamber 10 is formed coaxially with the longitudinal axis A.

In accordance with one example the cover 29 is removable (FIG. 3). The cover 29 is for example removably fixed to a cylindrical side wall 17 of the chamber 10 by vacuum connectors 31, such as double-claw clamps with a seal 32 disposed between the side wall 17 and the cover 29. A removable cover 29 enables access to the bottom of the chamber 10 to clean it without needing to remove the trap 4 from the pipe 8, in particular in the case of reception of debris too heavy to be able to be evacuated by a gas flow.

In accordance with one embodiment the trap 4 further includes at least one porthole 30 formed in the cover 29 and/or in the side wall 17 of the chamber 10.

The porthole 30 includes for example a duct 47 projecting from the cover 29 or from the side wall 17 of the chamber 10, as well as a transparent window 48 arranged at the end of the duct 47.

The porthole 30 in particular enables visual confirmation whether deposits, debris or other solid elements have accumulated in the chamber 10. It also enables installation of optical surveillance devices to assist the diagnosis of clogging.

The duct is for example inclined relative to the longitudinal axis A of the chamber 10 to facilitate the view of an operative. The window 48 of the porthole 30 may be removable, then forming an inspection hatch for example to enable the insertion of a vacuum cleaner nozzle into the duct.

Moreover, the internal walls of the trap 4 intended to be placed in communication with the flow of gas to be pumped, that is to say the side wall 17 and the internal wall of the cover 29 of the chamber 10, the walls of the outlet tube 11 and the walls of the deflector 18 may be coated with a chemically inert coating, such as dense Al₂O₃, Y₂O₃ or Y₂F₃, or a coating with non-stick and/or hydrophobic properties such as a NiP-PTFE or such as fluorinated or non-fluorinated polymer coatings or any other similar hydrophobic coating. These surface coatings favour the evacuation of the solid elements by limiting their adhesion to the walls.

Also, the trap 4 may include at least one injection nozzle 33 (shown schematically in FIGS. 4A and 4B), configured to inject a purge gas into the chamber 10 of the trap 4 for a predefined time.

The at least one injection nozzle 33 is for example arranged in the cover 29. It is for example oriented to direct a flow of purge gas in the direction of the bottom of the chamber 10 into the annular cover and/or in the direction of the concave screen 20 of the deflector 18.

The purge gas is for example nitrogen. Injection of a purge gas may enable replacement (or assistance) of the strong flow of gas to be pumped to evacuate the solid elements from the chamber 10 by aerodynamic entrainment. The injection nozzle 33 is for example configured to inject a strong flow of gas, for example greater than 200 slm (338 Pa·m³/s) in the situation where the process taking place in the chamber has no step of establishing a vacuum under the required conditions, that is to say generating the pumping of a strong flow of gas.

The injection nozzle 33 may moreover be configured to inject the purge gas in a pulsed manner, for example of the order of 10 to 20 pulses/second. Pulsed injection enables detachment of the solid elements from the curved surfaces of the deflector 18 and/or from the bottom wall 15 of the chamber 10 to be favoured.

An example of the functioning of the trap 4 will now be described with reference to FIGS. 2, 7A and 7B.

During the deposition step 102 (FIG. 7A), the flow of gas through the trap 4 is weak or moderate. Consequently, the gases circulate at low speed.

The concave screen 20 of the deflector 18 facing the inlet 12 of the chamber 10 guides the rising flow of gas along the edges of the screen 20, the flow of gas then being deflected toward the bottom of the chamber 10 by the cover 29 and the side wall 17 of the chamber 10. The annular cup of the bottom wall 15 of the chamber 10 then guides the rising flow of gas along the outlet tube 11. This flow of gas is then deflected toward the inlet 19 of the outlet tube 11 by the internal walls of the deflector 18, in particular of the skirt 21 and of the convex part of the screen 20. The weak or moderate flow of gas is not able to drive the solid elements out of the chamber 10, however. The largest particles, and even debris (schematically represented by stars), accumulate in the concave screen 20 of the deflector 18 facing the inlet 12 of the chamber 10. The particles of the solid byproducts generated in the reactor 3, finer than the debris but heavier than the gases (schematically represented by suns), fall to the bottom of the chamber 10 and accumulate by sedimentation in the annular cup. These solid elements and the gases may be cooled in contact with the bottom, itself cooled by the circulation of water in the double-bottom enclosure.

On the other hand, the gases exit the chamber 10 via the outlet tube 11. The gases are then cleansed of a fraction of the less mobile solid byproducts that remain trapped by gravity in the deflector 18 and in the bottom wall 15 of the chamber 10. Consequently, the solid byproducts are not wedged in the downstream pumping device 9. Only the more volatile deposits are entrained into the pumping device 9. These volatile deposits have less tendency to be stored in the pumps during the weak flow of gas phase (therefore at low flow speed).

At the end of the deposition step 102 the process gases 5 are evacuated from the reactor 3 in the phase 103 of establishing a vacuum (FIG. 7B). The evacuated flow of gas is strong, generally between 300 slm (507 Pa·m³/s) and 400 slm (676 Pa·m³/s) inclusive. If it is not sufficiently strong it is possible to inject a purge gas into the trap 4 via the injection nozzle 33, in a pulsed/intermittent manner or otherwise.

As during the deposition step 102, the particular curved shapes of the annular cup of the bottom wall 15 of the chamber 10 and of the concave screen 20 of the deflector 18 guide the flow of gas along the edges of the concave screen 20, then toward the bottom wall 15 of the chamber 10, and then along the outlet tube 11 as far as the inlet 19 of the outlet tube 11. Here the flow of gas is sufficiently strong, however, to entrain at least partly the solid elements freshly accumulated outside the chamber 10.

The solid elements can then be evacuated without waiting for the arrival of the active cleaning gases 7, in other words before conditions arise favourable to the polymerization chemical reactions.

Moreover, the high gas speeds induced by this strong flow of gas favour the transportation of the solid elements in the vacuum line 2 via the pumping device 9 situated downstream of the trap 4. Consequently, the solid elements do not remain for long in the pumping device 9.

The cyclic occurrence of this strong flow of gas in the reactor 3 after each deposition step 102 and before each cleaning step 105 is exploited here to sweep out the solid elements previously accumulated in the curved surfaces of the trap 4.

The trap 4 can therefore be cleansed of the majority of the solid elements before the arrival of the active cleaning gases. When the cleaning step 105 begins and the active gases are sent into the reactor 3, the solid elements from the deposition step 102 have been swept out by the flow of gas. This therefore minimizes the probability of encounters between the organic (or metallo organic) species from the deposition steps 102 and the acid/active/radical species from the cleaning steps 105, which limits the polymerization reactions. Maintenance of the trap 4 can therefore be reduced or even completely eliminated.

Although the example that has just been described relates to a use of the trap 4 in an installation 1 in which the flow of gas through the trap 4 enables the solid elements to accumulate by sedimentation in the annular cup during the deposition step 102 and the flow of gas through the trap entrains at least some of the solid elements out of the chamber 10 during the phase 103 of establishing a vacuum, the invention applies equally to all types of processes liable to generate solid elements of powder or polymer type.

If the process includes no step of establishing a vacuum or if the flow of gas is not sufficiently strong to evacuate the solid elements it is possible to inject a purge gas into the trap 4 via the injection nozzle 33, in pulsed or non-pulsed manner and for a predefined duration, that is to say alternately with periods with no injection via the nozzle 33.

FIGS. 8 and 9 show a second embodiment.

In this embodiment the deflector 35 includes a helix arranged coaxially with the axis A of a cylindrical chamber 10.

The helix is of uniflow cyclone type, that is to say generating a gas vortex favouring the separation of the solid elements from the gases in limited spaces. This embodiment of the deflector enables reduction of the overall size of the trap 4.

The helix may be fixed or mobile. The centre 36 of the helix may have a raindrop general shape, the tip of the drop being oriented toward the centre of the outlet tube 11.

Moreover, in this example the trap 4 includes a plurality of injection nozzles 33, each injection nozzle being directed toward the bottom wall 15. The injection nozzles are formed at the ends of tubes projecting from a ring connected to a source of gas under pressure, for example compressed air or nitrogen.

In operation, the helix generates a gas vortex enabling separation of the solid elements from the gases. The weak or moderate flow of gas is not able to entrain the solid elements out of the chamber 10. The solid elements drop to the bottom of the chamber 10 and accumulate by sedimentation in the bottom wall 15. These solid elements and the gases can be cooled in contact with the bottom, which itself may be cooled by the circulation of water in a double-bottom enclosure (not represented). The gases exit the chamber 10 via the outlet tube 11. The gases are then cleansed of a fraction of the less mobile solid byproducts that remain trapped by gravity in the bottom wall 15 of the chamber 10. The pumping device 9 is therefore able more easily to manage the flow of gas because it is partially cleansed of its solid charge.

When the evacuated flow of gas is again strong, because of the conditions of the process taking place in the reactor 3 or because a purge gas is injected into the trap 4 via the injection nozzles 3, the accumulated solid elements are at least partly evacuated from the chamber 10. These solids, the temperature of which has been reduced by their period in the bottom of the cooled chamber 10 are less cohesive and therefore not very liable to stick or to generate flakes or clusters.

FIGS. 10 to 12 illustrate a third embodiment.

In this example the outlet tube 11 is connected to the side wall 17 of the chamber 10. The side walls 17, 16 of the chamber 10 and of the outlet tube 11 are cylindrical for example, the cylindrical wall of the chamber 10 being coaxial with the pipe 8. The outlet tube 11 has an elbow shape for example, such as a 90° elbow.

Moreover, the bottom wall 15 is here produced in the form of a cup adjustable in height.

In accordance with one embodiment the trap 4 includes an actuating means 37 configured to cause the bottom wall 15 to slide in the chamber 10 in the direction of the axis A of the cylindrical chamber 10, that is to say vertically. The actuating means 37 is for example a linear actuator fastened to a rod 38 connected to the cup. The rod 38 is for example connected to the centre and back of the cup and passes through a double bottom 39 of the chamber 10 in a sealed manner, for example by means of a metal bellows 44 welded on the one hand to the back of the cup and on the other hand to the double bottom 39 of the chamber 10 (in dashed line in FIG. 10).

Adjusting the heightwise positioning of the cup enables optimization of the functioning of the trap 4 by accumulation or sweeping out of the solid elements. The cup is raised so as to move toward the inlet 19 of the outlet tube 11 when the flow of gas is weak or moderate to improve the sweeping out effect and lowered when the flow of gas is strong.

Moreover, in this embodiment, and seen better in FIG. 11, the deflector 40 has a frustoconical duct general shape forming an inlet guide. The wider side of the frustoconical duct corresponds for example to the dimension of the inlet 12 of the chamber 10. The resulting funnel orients the gases and the dust toward the cup-shaped bottom wall 15.

FIG. 11 shows an example of a deflector having a frustoconical duct general shape forming an inlet guide, the axis of the duct being coaxial with the axis of the chamber 10.

In accordance with another example seen in FIG. 12, the frustoconical duct of the deflector 40 forming the inlet guide is off-centred. The axis B passing through the centres of the circles at the ends of the conical duct is not parallel to the axis A of the chamber 10.

FIGS. 13 and 14 show a variant embodiment of the deflector 45.

In this embodiment the deflector 45 has a bevelled cylindrical duct general shape forming an inlet guide, the bevel being open at a lower end of the deflector 45.

Another object of the present invention is a vacuum line 2 for which temperature management is separated in two zones (FIG. 1).

The vacuum line 2 is configured to be heated only over a first pipe portion 41, for example to below 100° C., such as to 170° C.

This first pipe portion 41 is for example situated between the reactor 3 and the trap 4.

When the vacuum line 2 does not include a trap 4 this first heated pipe portion 41 ends less than one metre from the pumping device 9. That distance enables prevention of transmission of heat from the first pipe portion 41 to the second pipe portion 46 including the pumping device 9.

The vacuum line 2 may include a variable conductance regulator valve 42 on this first pipe portion 41, at the outlet of the reactor 3, to control the pressure of the gases in the reactor 3.

The vacuum line can also include a heated or unheated powder trap (not represented) in this first pipe portion 41, downstream of the regulator valve 42 in the direction of the pumped gases.

Heating this first pipe portion 41 in particular enables heating of the gases that have been cooled by adiabatic expansion due to the effect of rapid pressure variations generated by the movements of the regulator valve 42, to maintain them in gas form by preventing them from condensing or solidifying.

The second pipe portion 46, including the pumping device 9, and possibly an isolator valve 43 of the pumping device 9, and where applicable a trap 4 as described above, is not heated. In some cases this second pipe portion 46 may even be cooled. The unheated or cooled solid elements remain in powder form. They are easy to evacuate by pumping and the reduced temperature enables slowing of the appearance of unwanted chemical reactions upstream of the pumping device 9.

FIGS. 15 and 16 show a variant embodiment.

In this example the trap 4 includes first and second portholes 30a, 30b formed in the side wall 17 of the chamber 10. The trap 4 further includes an optical surveillance device configured to direct light through the first porthole 30a and to measure the light crossing the chamber 10 through the second porthole 30b. Observation of the light in the chamber 10 enables the deposits present in the chamber 10 to be determined or even quantified.

The portholes 30a, 30b and where applicable the porthole 30 formed in the cover 29 may include an annular curtain device 49 configured to form a screen of purge gas in front of a window 48 of the porthole 30a, 30b, 30 in order to prevent deposition of a fine powder film on the surface of the window 48 that could compromise transparency.

The annular curtain device 49 includes for example a ring arranged in the duct 47 near the window 48. The ring features a plurality of gas injection orifices, for example regularly distributed circumferentially. The annular curtain device 49 further includes a feed 50 for a purge gas, such as nitrogen, configured to inject purge gas into the duct 47 through the orifices in the ring. A gas curtain can thus be formed between the duct 47 and the window 48 to form a screen preventing the deposition of powders on the window 48.

1.-26. (canceled)

27. A trap for a vacuum line configured to be mounted on a pipe connected to a reactor, the trap comprising:
a chamber comprising an inlet and a bottom wall;
an outlet tube comprising another inlet and being in communication with the chamber,
wherein the inlet of the chamber and the outlet tube are configured to be connected, respectively, to the pipe of the vacuum line and to permit passage of a flow of gas to be pumped coming from the reactor; and
a deflector disposed between the inlet of the chamber and the another inlet of the outlet tube,
wherein the bottom wall of the chamber is disposed below the another inlet of the outlet tube,
wherein the bottom wall is an annular cup or an adjustable height cup, and is conformed so as to cooperate with the deflector to permit an accumulation of solid elements in the bottom wall when the flow of gas to be pumped is reduced and to expel the solid elements from the chamber by aerodynamic entrainment when the flow of gas to be pumped is increased.

28. The trap according to claim 27,
wherein the outlet tube penetrates into the chamber, and
wherein the bottom wall surrounds the outlet tube and is an annular cup.

29. The trap according to claim 27,
wherein the deflector includes a concave screen facing the inlet of the chamber, and
wherein edges of the concave screen are extended by a skirt surrounding the outlet tube.

30. The trap according to claim 27, wherein the deflector is fastened to a tubular base of the outlet tube, the tubular base being removable.

31. The trap according to claim 27, wherein the outlet tube further comprises at least one tubular raiser spacer configured to raise the deflector.

32. The trap according to claim 27, wherein the deflector includes a helix arranged coaxially with a longitudinal axis of the chamber.

33. The trap according to claim 27, wherein side walls of the chamber and of the outlet tube are cylindrical and coaxial.

34. The trap according to claim 27,
wherein the outlet tube is connected to a side wall of the chamber, and
wherein the bottom wall is an adjustable height cup.

35. The trap according to claim 27, further comprising an actuation means configured to cause the bottom wall to slide in the chamber in a direction of a longitudinal axis of the chamber.

36. The trap according to claim 34, wherein the deflector has a frustoconical duct shape forming an inlet guide.

37. The trap according to claim 36,
wherein the frustoconical duct has an axis that is coaxial with the longitudinal axis of the chamber, and
wherein the chamber has a general cylindrical shape.

38. The trap according to claim 36, wherein the frustoconical duct shape is off-center.

39. The trap according to claim 34, wherein the deflector has a beveled general cylindrical duct shape forming an inlet guide, the bevel being open at a lower end of the deflector.

40. The trap according to claim 27, further comprising a cooling device configured to cool the bottom wall.

41. The trap according to claim 40,
wherein the cooling device is a double-bottom enclosure closed by the bottom wall of the chamber, and
wherein the double-bottom enclosure has a liquid inlet and a liquid outlet configured to permit circulation of a cooling liquid.

42. The trap according to claim 27,
further comprising internal walls configured to be placed in communication with the flow of gas to be pumped,
wherein the internal walls are coated with a chemically inert coating.

43. The trap according to claim 27, further comprising at least one injection nozzle configured to inject a purge gas into the chamber in a direction of the bottom wall.

44. The trap according to claim 43, wherein the injection nozzle is configured to inject a purge gas in a pulsed manner.

45. The trap according to claim 27, further comprising at least one porthole formed in a cover of the chamber and/or in a side wall of the chamber.

46. The trap according to claim 45, further comprising:
first and second portholes formed in the side wall of the chamber; and
an optical surveillance device configured to send light through the first porthole and to measure the light crossing the chamber through the second porthole.

47. The trap according to claim 45, wherein the at least one porthole includes an annular curtain device configured to form a purge gas screen in front of a window of the at least one porthole.

48. An installation, comprising:
a vacuum line including a pipe and a pumping device;
a reactor including an outlet, the outlet being connected to the pipe; and
a trap according to claim 27, mounted on the pipe upstream of the pumping device in a direction of circulation of gases to be pumped.

49. The installation according to claim 48, wherein the reactor is configured for fabrication of semiconductors, including deposition of thin layers by alternating steps of deposition followed by steps of establishing a vacuum, and cleaning steps.

50. The installation according to claim 48, wherein the vacuum line is configured to be heated only over a first pipe portion disposed between the reactor and the trap.

51. A method of operating a trap in an installation according to claim 48, wherein:
during a deposition step, a reduced flow of gas crosses the trap and enables solid elements to accumulate by sedimentation in the bottom wall, and
during a phase of establishing a vacuum, an increased flow of gas crosses the trap and at least partly entrains the solid elements out of the chamber toward the pumping device.

52. The method according to claim 51, further comprising injecting a purge gas into the trap to entrain at least partly the solid elements out of the chamber.
